(19) United States
(12) Patent Application Publication
(10) Pub. No.: US 2007/0205453 A1
(43) Pub. Date: Sep. 6, 2007

(54) Semiconductor device and method for manufacturing the same

(76) Inventor: Hideyuki Ando, Miyagi (JP)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/641,011

(22) Filed: Dec. 19, 2006

(30) Foreign Application Priority Data
Mar. 3, 2006 (JP) 2006-057857

(51) Int. Cl. H01L 29/76

(52) U.S. Cl. 257/314

(57) ABSTRACT

A semiconductor device prevents diffusion of electric charges retained in silicon nitride films of a MOSFET during a writing operation and has a favorable charge retention property. The silicon nitride films, each of which functions as a memory functional body, are formed at a thickness of 100 Å at a maximum. Each of the silicon nitride film dose not exist on each side surfaces of a gate electrode but exists only on each silicon oxide films between the gate electrode and a substrate, so that each of the silicon nitride films is small in volume.

### BACKGROUND OF THE INVENTION

1. Field of the Invention

The present invention relates to a semiconductor device including a field effect transistor provided with a memory functional body for retaining an electric charge and a method for manufacturing the same.

2. Description of the Related Art

A nonvolatile memory device provided on a semiconductor device has been conventionally known, which is a single metal-oxide-semiconductor field effect transistor (MOSFET) having a two-bits storage function, so-called “one cell with two-bits function”. This nonvolatile memory device further includes a memory functional body formed by a silicon nitride film provided on a side surface of a gate electrode of the MOSFET and on an upper surface of a substrate which surface is laterally adjacent to the gate electrode.

A conventional semiconductor device including charge storage films is disclosed by, for example, a Japanese Patent Kokai No. 2004-34927. The conventional semiconductor device provided with two silicon nitride films as charge storage films has the following FET structure. That is, three regions including a channel region on which a gate electrode part is formed, a source region, and a drain region are formed in a semiconductor substrate. The channel region is sandwiched by the source and drain regions which are separate from each other. The channel region is formed by doping impurities of a first conductive type into the semiconductor substrate. The source and drain regions are formed by doping impurities of a second conduction type, whose conductivity is opposite to the first conductive type, into the semiconductor substrate. The gate electrode part including a gate oxide film and a gate electrode formed on the gate oxide film is formed on the upper surface of the channel region. The MOSFET is constructed with the source, drain, and channel regions, and the gate electrode part.

The semiconductor device according to the prior art is further provided with silicon oxide films having a uniform thickness. With the silicon oxide films, both side surfaces of the gate electrode part and upper surfaces of the semiconductor substrate laterally adjacent to the gate electrode part are uniformly covered. The silicon oxide film through which electrons are carried into the silicon nitride films formed thereon is called a tunneling oxide film. Electric charges of the electrons are source of data memory. The silicon oxide films are covered with the silicon nitride films, each of which having a function of accumulating electric charges. This silicon nitride film has an electric charge storage function, that is, a function of accumulating electrons carried thereto during a data writing operation and retaining the electrons therein.

It is important in the conventional semiconductor device that the silicon nitride film keeps the amount of the electric charge carried thereto constant without changing and decreasing.

However, in the conventional semiconductor device provided with the silicon nitride film having the electric charge storage function as a memory functional body, there is a possibility that the electric charges retained in the silicon nitride films diffuse during a completed semiconductor device operates or various stresses such as a thermal stress etc. are applied. Such charge diffusion remarkably occurs in the silicon nitride film having a thicker thickness. The reasons will be explained as follows.

First of all, the electric charge tends to be retained in the silicon nitride film close to the source and drain regions of the semiconductor substrate. As increasing the amount of electric charges retained in the silicon nitride film close to the source and drain regions of the semiconductor substrate, data information is likely to be retained. As increasing the amount of the electric charges carried into the lower part of the silicon nitride film close to the substrate, the semiconductor device has a high charge retention performance.

Secondly, the silicon nitride film has much spots, so-called traps, in which the electric charges are retained. When an electric field is applied to the silicon nitride film in a direction of the film, that is, in a vertical direction with respect to the surface of semiconductor substrate during the operation of the semiconductor device, the electric charges retained in one of the traps will transfer to another traps according to the law of electrostatic-induction. As increasing the thickness of the silicon nitride film, the amount of the traps increases. Therefore, the electric charge is likely to transfer and diffuse in the vertical direction in the silicon nitride film as increasing the thickness of the silicon nitride film.

As increasing the thickness of the silicon nitride film, the electric charges diffuse to a long-range region of the silicon nitride film, thus increasing a probability of diffusion of the electric charges.

The above-mentioned prior art has the silicon nitride films with which both side surfaces of the gate electrode and upper surfaces of the substrate which is laterally adjacent to both side surfaces of the gate electrode are covered. In a part of the silicon nitride film with which the side surface of the gate electrode part is covered, a direction where the thickness increases corresponds to a horizontal direction with respect to the upper surface of the semiconductor substrate. The thickness of the side surface portion of the silicon nitride film in a vertical direction with respect to the upper surface of the semiconductor substrate is equal to the height of gate electrode part. The part of the silicon nitride film, with which the side surface of the gate electrode part is covered, has a thickness equal to the height of gate electrode part even if the silicon nitride film of thin thickness is grown. The electric charges, which are retained in the part of the silicon nitride film with which the side surface of the gate electrode part is covered, can transfer to a long-range region vertically. Thus, even if the silicon nitride film of thin thickness is formed, there is the possibility that the electric charge diffuses in the part of the silicon nitride film, with which the side surface of the gate electrode part is covered.

The electrical charge diffusion causes a decrease in the amount of the electric charge retained in the lower part of the silicon nitride, that is, close to the semiconductor substrate, thus damaging the electric charge retention property of the semiconductor substrate.

### SUMMARY OF THE INVENTION

It is an object of the present invention to provide a semiconductor device that can suppress diffusion of electric charges carried into silicon nitride films in a MOSFET during a writing operation and a method for manufacturing the semiconductor device.

According to a first aspect of the present invention, there is a provided a semiconductor device comprising a semiconductor substrate having an element region and a gate electrode part which includes a gate oxide film and a gate electrode formed on the gate oxide film, the gate electrode part being formed on an upper surface of a channel region formed at the element region, first and second main electrode regions formed in the semiconductor substrate, both of which sandwich the channel region, silicon oxide films whose thickness are thinner than that of the gate electrode part and substantially uniform, each of the silicon oxide films being formed as an integrated combination of a peripheral silicon oxide film with which an upper surface of the semiconductor substrate surrounding a side of the gate electrode part is covered and a side silicon oxide film with which a side surface of the gate electrode part is covered, silicon nitride films whose thickness are 100 Å at a maximum, with which upper surfaces of the peripheral silicon oxide films are covered, and side walls respectively formed on upper surfaces of the silicon nitride films, each of which are separated from the side silicon oxide film.

According to the first aspect of the present invention, each of silicon nitride films for retaining electric charges has a thickness of 100 Å at a maximum. When the electrons are carried into silicon nitride films during a writing operation, the amount of the electric charges retained in the lower part of the nitride films increases in comparison with the silicon nitride films having a thickness more than 100 Å. The electric charges accumulated are likely to be retained in the silicon nitride film, resulting in a favorable charge retention property.

In addition, the silicon nitride films provided with the semiconductor substrate have thin thickness, and thus decreases their volume compared to that having a thicker thickness. The number of the charge traps existing in the silicon nitride films, and in particular, existing in the silicon nitride films far from the semiconductor substrate 11, decreases. The semiconductor device according to the first aspect has less charge traps far from the semiconductor substrate, thus preventing the diffusion of the electric charges retained in the silicon nitride films during a operation of the semiconductor device, that is, an electric field is applied to the device, and under various type of stress, for example, a thermal stress.

According to a second aspect of the present invention, there is a provided a method for manufacturing the semiconductor device of the first aspect of the present invention having the steps of a first step of doping impurities having a first conductive type into an element region of a semiconductor substrate, so as to form a first conductive type impurity region, a second step of forming a gate electrode part including a gate film and a gate electrode on a part of an upper surface of the first conductive type impurity region, a third step of forming a silicon oxide precursor film whose thickness is substantially uniform and thinner than that of the gate electrode part, with which a surface of the semiconductor substrate including the gate electrode is covered, a fourth step of forming a silicon nitride precursor film having a thickness of 100 Å at a maximum, with which a surface of the silicon oxide precursor film is fully covered, a fifth step of doping impurities having a second conductive type whose conductivity is opposite to the first conductive type into the first conductive type impurity region while using the gate electrode as a mask, so as to form a MOSFET including first and second main electrode regions having the second conductive type and a channel region which exists under the gate electrode part and is sandwiched by the first and second main electrode regions, a sixth step of forming a side wall precursor film with which a surface of the silicon nitride precursor film is fully covered, a seventh step of removing the side wall precursor film and a laminated layer having the silicon nitride precursor film and the silicon oxide precursor film excluding peripheral portions surrounding the gate electrode until an upper surface of the gate electrode and an upper surface of the semiconductor substrate except for the peripheral portions are exposed, so as to form side walls from the side wall precursor film, silicon nitride films from the silicon nitride precursor film, and silicon oxide films from the silicon oxide precursor film, each of the silicon oxide films is an integrated combination of a peripheral silicon oxide film with which an upper surface of the semiconductor substrate surrounding the gate electrode part is covered and a side silicon oxide film with which a side surface of the gate electrode part is covered, and an eighth step of removing side silicon nitride films from the silicon nitride films, each of the side silicon nitride films existing between a side surface of the side walls facing the gate electrode part and a side surface of the gate electrode part, so as to form peripheral silicon nitride films, each of which exists on an upper surface of the peripheral silicon oxide film.

According to the second aspect of the present invention, the side silicon nitride films which existing between side surfaces of the side walls facing the gate electrode part and side surfaces of the gate electrode part is removed. The semiconductor device manufactured while using the method according to the second aspect eliminates the silicon nitride films which are formed on the side surface of silicon oxide film facing the gate electrode from a conventional semiconductor device. Therefore, an increasing in the film thickness of the silicon nitride films which are formed on the side surfaces of silicon oxide film facing the gate electrode is prevented in a direction perpendicular to the surface of the semiconductor substrate. Therefore, the electric charges retained in the silicon nitride film are confined into each of the silicon nitride films, and thus prevented from moving to a part of the silicon nitride film far from semiconductor substrate.

### BRIEF DESCRIPTION OF THE DRAWINGS

FIG. 1 is a cross-sectional view illustrating a semiconductor device according to the present invention formed in a first step;

FIG. 2 is a cross-sectional view illustrating a semiconductor device formed in a second step;

FIG. 3 is a cross-sectional view illustrating a semiconductor device formed in a third step;

FIG. 4 is a cross-sectional view illustrating a FET storage cell formed in a fourth step;

FIG. 5 is a cross-sectional view illustrating a semiconductor device formed in a fifth step;

FIG. 6 is a cross-sectional view illustrating a semiconductor device formed in a sixth step;

FIG. 7 is a cross-sectional view illustrating a semiconductor device formed in a seventh step;

FIG. 8 is a cross-sectional view illustrating a semiconductor device formed in an eighth step.

### DETAILED DESCRIPTION OF THE INVENTION

A semiconductor device according to the present invention and a method for manufacturing the semiconductor device will be described with reference to the drawings. Each of the drawings only illustrates shapes of, sizes of, and configurations of components the extent to which the present invention is understood. Components of the present invention are not limited to those of the embodiments shown in the drawings.

A method for manufacturing a semiconductor device provided with a MOSFET including silicon nitride films having electric charge storage function will be described. The silicon nitride films having a thickness of 100 Å at a maximum is formed by removing a side surface part thereof facing to a gate electrode part. The method includes a first to a seven steps. Each of the steps is sequentially described from the first step.

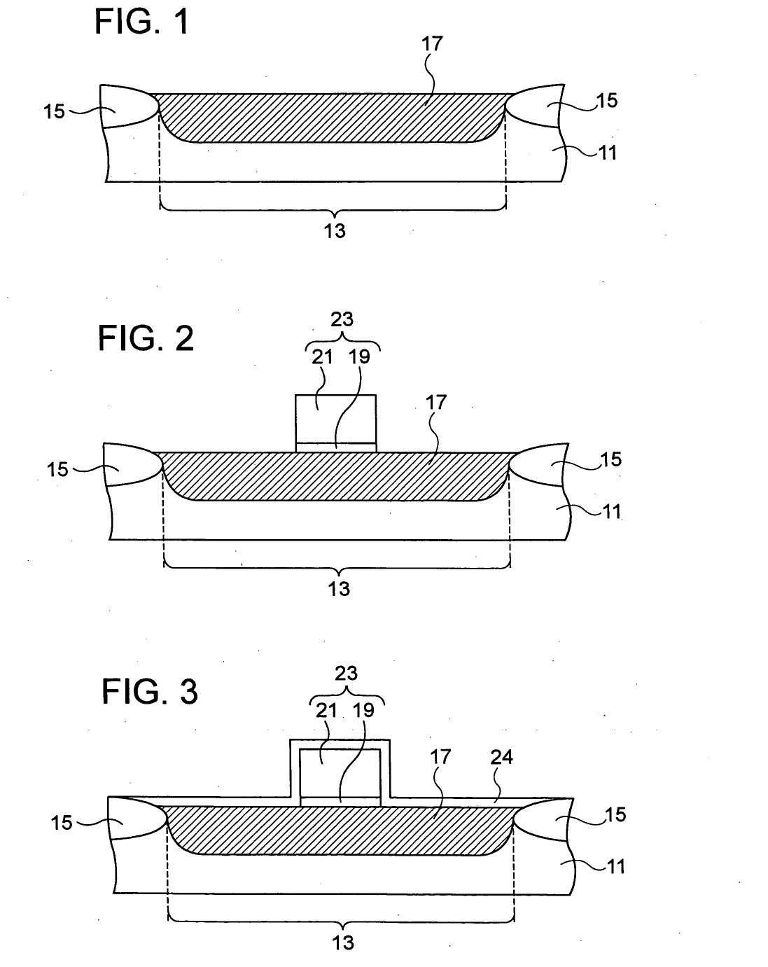

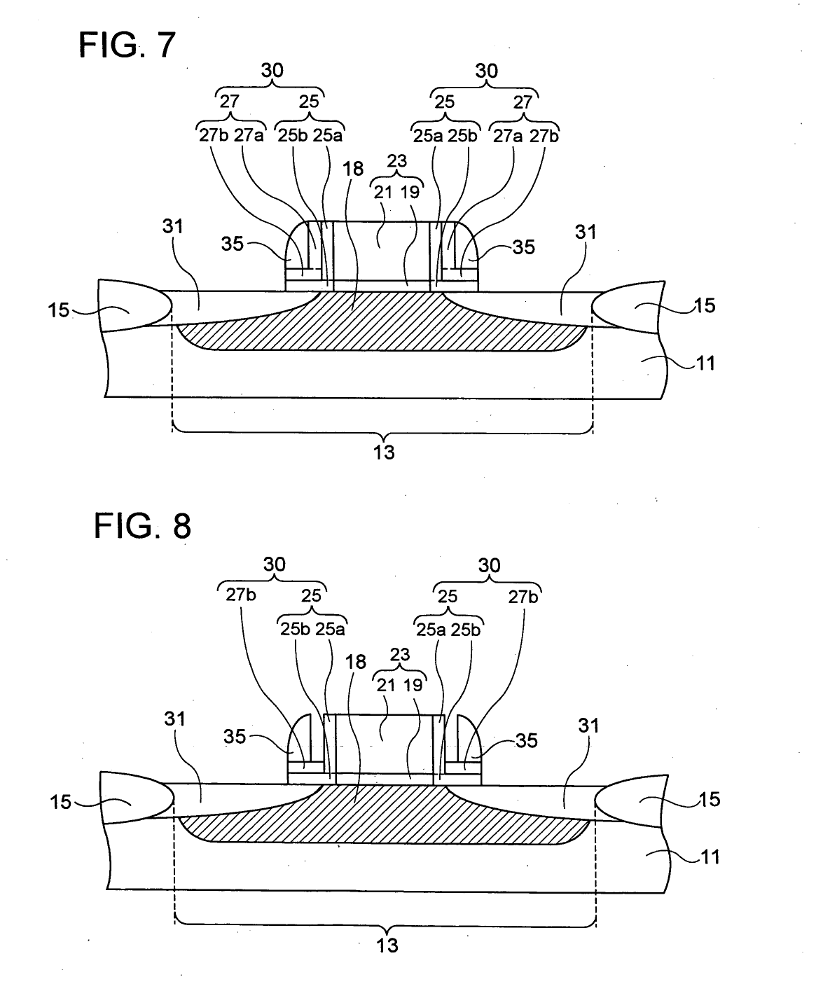

FIGS. 1 to 8 are cross-sectional views illustrating semiconductor devices formed in each of steps.

In a first step, a first conductive type impurity region 17 is firstly formed by doping impurities having a first conductive type into an element region 13 of a semiconductor substrate 11.

The semiconductor substrates 11 prepared in the first embodiment is, for instance, a single-crystal Si substrate or other conventional semiconductor substrates compounded of Si. In the semiconductor substrate 11, the element region 13 is enclosed by element isolation regions 15 which electrically isolate plural of the element regions 13 from each other. The element isolation regions 15 are formed by use of such a conventional method as a Local oxidation of silicon (LOCOS) method and a Shallow trench isolation (STI) method etc.

The element region 13 is changed into a region into which impurities having the first conductive type are diffused. That is, the first conductive type impurity region 17 is formed by doping impurities of the first conductive type into the element region 13 which isolates the element isolation regions 15. The impurity doping is performed in a view to control a threshold value of a MOSFET in a channel region to be formed in a later step. The impurity doping is performed by using a conventional technique such as a S/D (source and drain) implantation method. When an n-type MOSFET (PMOS) is intended to be formed, n-type impurities such as As (arsenic), P (phosphorus), etc. may be doped into the element region. When a p-type MOSFET (PMOS) is intended to be formed, p-type impurities such as Ga (gallium), In (indium), etc. may be doped into the element region. Suitable impurities for a designed MOSFET may be doped.

In a second step, a gate electrode part 23 including a gate electrode 21 and a gate oxide film 19 shown in FIG. 2 is formed on an upper surface of the semiconductor substrate 11, that is, a region where a channel region of the first conductive impurity region will be formed in a later step.

The gate electrode 21 and gate oxide film 19 are formed by use of a conventional method. That is, the gate oxide film 19 is formed on the element region 13 by use of a conventional thermal oxidation method. A poly-Si (polysilicon) film and a silicide film are sequentially deposited on the gate oxide film 19 by use of a chemical vapor deposition (CVD) etc., so as to form the gate electrode 21. The silicide film constructing the gate electrode 21 may be formed by depositing a conventional silicide such as compounds of Si (silicon) and W (tungsten). The gate oxide film 19 and gate electrode 21 is patterned by use of conventional methods such as a photolithographic etching method, a dry etching method, and other methods, so as to form the gate electrode part 23 shown in FIG. 2.

In a third step, a silicon oxide precursor film 24, which is thinner than the gate electrode part 23 and substantially has a uniform thickness, is formed, with which a surface of the semiconductor substrate 11 including the gate electrode part 23 is fully covered as shown in FIG. 3.

The silicon oxide precursor film 24 is formed by use of a conventional thermal oxidation method similarly to the gate oxide film 19 in the second step. The silicon oxide precursor film 24 will be removed in a later step excluding a side silicon oxide film with which both sides of the gate electrode part 23 are covered and a peripheral silicon oxide film with which peripheral regions of the gate electrode part 23 are covered. A part of the silicon oxide precursor film 24 including side silicon oxide film and the peripheral silicon oxide film both of which are not removed will be formed as silicon oxide films in a later step. The silicon oxide film, called tunneling oxide film, has a function that electrons, which is a source of data memory, are carried into the silicon nitride film formed thereon. Accordingly, it is required that the thickness of silicon oxide film has the extent to which the electrons can tunnel into the silicon nitride film. A preferable minimum thickness of the silicon oxide film is 30 Å. As stated above, it is likely that electric charges are likely to be retained at a region of the silicon nitride film close to the first and second main electrode regions 31 of semiconductor substrate 11. A distance between the silicon nitride film and semiconductor substrate 11 increases if the silicon nitride film is thickly formed more than required, thus increasing a distance between the electric charge retained in the silicon nitride film and the semiconductor substrate. Therefore, the thickness of the silicon nitride film should be set to be extent to which the electric charges are retained. The silicon oxide precursor film 24 that has the thickness of 30 to 200 Å may be formed. In the range of the thickness of 30 to 200 Å, the silicon nitride film can retain the electric charge. If the silicon nitride film can retain the electric charge, the thickness of the silicon nitride film is not limited to the thickness of 30 to 200 Å.

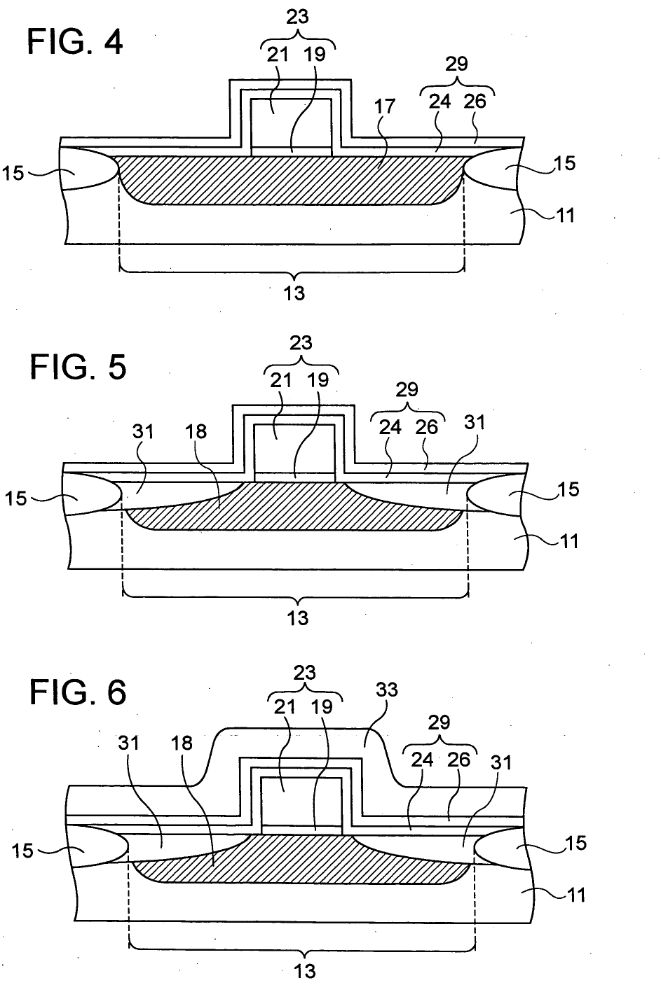

In a fourth step, a silicon nitride film 26 with which a surface of the silicon oxide precursor film 24 is covered is formed as shown in FIG. 4. A thickness of the silicon nitride film 26 is 100 Å at a maximum.

The silicon nitride precursor film 26 is formed by use of a conventional chemical vapor deposition (CVD) method. This silicon nitride precursor film 26 will be removed in a later step excluding a part with which an upper surface of the silicon oxide film is covered. And, the part of silicon nitride precursor film 26 that exists on the upper surface of the silicon oxide film will become a silicon nitride film. In the semiconductor device while using the first embodiment, the silicon nitride film operates as a memory functional body, accumulates electric charges carried thereinto during a writing operation, and retains the electric charges therein. And, as explained above, the possibility increases that the retained electric charge diffuses in the silicon nitride film as increasing the thickness of the silicon nitride film. The silicon nitride precursor film 26 is formed below 100 Å. When a thin silicon nitride film beyond necessity is formed, the amount of the accumulated electrons will decrease. When the thickness of the silicon nitride film is extremely thin, the films degrade during the production processes, thus disturbing stability of the device. Therefore, the silicon nitride precursor film 26 should be formed below 100 Å, and favorably should be formed in the range of 50 to 80 Å.

The silicon nitride precursor film 26, whose thickness is in the range of 50 to 80 Å or below 100 Å, is deposited by use of the chemical vapor deposition method under the following conditions, for example. The deposition is performed at temperature of 755° C. under a reactive pressure of 0.25 Torr in mixed gas of NH₃ (ammonia) and SiH₂Cl₂ (dichlorosilane) at a rate of 10:1. The silicon nitride precursor film 26 may be fabricated at a deposition rate of about 20 Å/min. The silicon nitride precursor film 26 having the thickness of 50 to 80 Å is formed under the above condition. If the silicon nitride precursor film 26 having the thickness of 50-80 Å is achieved, the temperature, the partial pressure, the reactive pressure, and the processing time are not limited to the above condition.

A layered product having the silicon nitride precursor film 26 formed in the fourth step and the silicon oxide precursor film 24 formed in the third step is shown as a laminated film 29 as shown in FIG. 4.

In a fifth step, a MOSFET structure having first and second main electrode regions 31 and a channel region 18 which is under the gate electrode part 23 and sandwiched by the first and second main electrode regions 31 is formed. The channel region 18 is formed in the first conductive type impurity region 17 to which the second conductive type impurities are not doped, so that the first conductive type impurity region 17 is sandwiched by the first and second main electrode regions 31.

The MOSFET structure includes the gate electrode part 23 formed on the element region 13 of the semiconductor substrate 11 in the second step, the first and the second main electrode regions 31 separated from each other which are formed in the semiconductor substrate 11, and the channel region 18 sandwiched between the first and the second main electrode regions 31. The first and second main electrode regions 31 are used as source and drain electrodes.

Impurities of the second conductive type whose conductivity is opposite to the first conductive type are doped into the first conductive type impurity region 17 while using the gate electrode as a mask. It is to be noted that the second conductive type impurities are not doped into the first conductive type impurity region 17 under the gate electrode part 23 which is masked with the gate electrode. The first conductive type impurity region 17 to which the impurities of the second conductive type is not doped corresponds to the channel region 18. On the other hand, the first conductive type impurity region 17, into which impurities of the second conductive type are doped, corresponds to the first and second main electrode regions 15 which sandwich the channel region 18.

The impurities of the second conductive type are also doped into the gate electrode 21 of the gate electrode part 23, and the impurities are also doped into the silicon oxide precursor film 24 and the silicon nitride precursor film 26 which are formed on the first conductive type impurity region 17. The gate electrode 21 having the second conductive type is formed, thus improving a conductivity of the gate electrode. The doping of impurities of the second conductive type in this step is performed by use of a S/D implantation method. The first and second main electrode regions 31 described above are used for source and drain regions.

The impurities of the second conductive type are lightly doped into the first and second main electrode regions 31 in the fifth step.

The impurities of the second conductive type doped into the first and second main electrode regions 31 in the fifth step are either p-type impurities such as Ga (gallium), In (indium), and B (boron), etc. which form a PMOS transistor structure or n-type impurities such as As (arsenic) and P (phosphorus), etc. which form a NMOS transistor structure. Suitable impurities corresponding to the design may be selected. The doping impurities are not limited to the above mentioned impurities.

In a sixth step, a side wall precursor film 33, with which a surface of the silicon nitride precursor film 26 are covered, is formed as shown in FIG. 6.

This Side wall precursor film 33 is formed by depositing the silicon oxide film etc. on the silicon nitride precursor film 26 by use of a conventional CVD method.

In a sixth step, the side wall precursor film 33 and a laminated layer 29 having the silicon nitride precursor film 26 and the silicon oxide precursor film 24 are removed excluding peripheral portions of the side wall precursor film 33 and a laminated layer 29 having the silicon nitride precursor film 26 and the silicon oxide precursor film 24 on the semiconductor substrate 11 surrounding both sides of the gate electrode part 23 until the an upper surface of the gate electrode part 23 and upper surfaces of the semiconductor substrate 11 excluding the peripheral portions are exposed. Two side walls 35 are formed from the side wall precursor film 33. Two silicon nitride films 27 are formed from the silicon nitride precursor film 26. Peripheral silicon oxide films 25b with which upper surfaces of the semiconductor substrate surrounding both sides of the gate electrode part 23, and side silicon oxide films 25a with which both side surfaces of said gate electrode part 23 are covered are formed from the silicon oxide precursor film 24. A silicon oxide film 25 is an integrated film of the peripheral silicon oxide film 25b and the side silicon oxide film 25a. Each of the silicon nitride films 27 is an integrated film of the peripheral silicon nitride film 27b with which the peripheral silicon oxide film 25b is covered and a side silicon nitride film 27a with which a side surface of the side silicon oxide film 25a is covered.

The side walls 35 together with the gate electrode part 23 will be used for a mask in a later step where LDD (Lightly Doped Drain) regions of low impurity concentration are defined from highly doped regions. Laminate layers 30 having residual films of the side wall precursor films 33, the silicon nitride films 27, and the silicon oxide films 25 which are not removed exist in a peripheral part of the gate electrode part 23. A width of the laminate layer 30 may be arbitrarily and suitably changed in accordance with a width of LDD region.

In an eighth step, the side silicon nitride films 27a, each of which exists between the side surface of gate electrode part 23 and a side surface of the side wall 35 facing the side surface of the gate electrode part 23, are removed from the silicon nitride films 27 excluding the peripheral nitride films 27b that remain on the upper surfaces of the peripheral silicon oxide films 25b, whereby to form a structural body shown in FIG. 8

In this eighth step, only the side silicon nitride films 27a of silicon nitride films 27 are selectively removed. The side silicon nitride films 27a are removed by use of a well-known dry etching method.

The second conductive type impurities are doped into the first and second main electrode regions 31 again after the eighth step, whereby to form highly-doped regions of the first and second main electrode region. Therefore, each of the first and second main electrode regions includes the highly-doped region which do not overlap with the peripheral silicon nitride film 27b and the lightly doped region which exists below the peripheral silicon nitride film 27b.

Each of the LDD region is formed for the sake of a control of a short-channel effect etc. Impurities of the second conductive type are doped into the first and second main electrode regions 31 in the fifth step, whereby to form the first and second main electrode regions 31 having the second conductive type. The Impurities of the second conductive type are doped again into the first and second main electrode regions 31, parts of which are masked, whereby to form the highly doped region and the LDD region, both of which have the second conductive type in each of the first and second main electrode regions 31. When the Impurities of the second conductive type are doped again into the first and second main electrode regions 31, the impurities are not doped into a region where is masked by the side wall 35 and gate electrode 23. The impurities of the second conductive type are doped into the first and second main electrode regions 31 outside from the side wall 35, whereby to form the first and second main electrode regions having a high density of the impurities. The first and second main electrode regions under the side wall 35 has the LDD regions. The first and second main electrode regions where the impurity concentration is low correspond to the LDD regions.

The semiconductor device formed in the eighth step may be covered with a silicon oxide film for preventing a metal pollution after the second conductive impurities are doped. It is should be noted that silicon oxide film for preventing the metal pollution may be filled a gap between the side wall 35 and side silicon oxide film 25b where the side silicon nitride films 27a are not removed in the eighth step (not shown in figures).

According to the semiconductor device manufactured while using the first embodiment, the silicon nitride films, that is, the peripheral nitride film 27b, which plays a role of charge retention as a memory functional body, has the thickness that is 100 Å or less. When the electron is carried into the peripheral nitride films 27b during the writing operation, the amount of the electric charges retained in the lower part of peripheral nitride films 27b increases, compared with a peripheral nitride films 27b having a thicker film. The accumulated electric charges are likely to be retained in peripheral nitride films 27b, resulting in a favorable charge retention property.

According to the method of the present invention for manufacturing the semiconductor device, the thickness of the silicon nitride films, that is, the peripheral nitride films 27b are set to 50 to 80 Å, thus preventing the electric charges retained in the peripheral nitride films 27b, which are sources of information data, from decreasing excessively, and a deterioration of stability of the films during the steps which originates from the thickness of the peripheral nitride films 27b is extremely thin.

According to the semiconductor device manufactured while using the method of the present invention, the silicon nitride films, that is, the peripheral nitride films 27b, provided with the semiconductor substrate have thin thickness, and thus decreases their volume compared to that having a thicker thickness. The number of the charge traps existing in the peripheral nitride films 27b, and in particular, existing in the peripheral nitride films 27b far from the semiconductor substrate 11, decreases. The semiconductor device while using the first embodiment has less charge traps far from the semiconductor substrate 11, thus preventing the diffusion of the electric charges retained in the peripheral nitride films 27b during a operation of the semiconductor device, that is, an electric field is applied to the device, and under various type of stress, for example, a thermal stress.

According to the method for manufacturing the semiconductor device, the side silicon nitride films 27a are removed in the eighth. The semiconductor device manufactured while using the first embodiment eliminates the silicon nitride film which is formed on the side surface of silicon oxide film facing the gate electrode from a conventional semiconductor device. Therefore, an increasing in the film thickness of the silicon nitride film which is formed on the side surface of silicon oxide film facing the gate electrode is prevented in a direction perpendicular to the surface of the semiconductor substrate. Thereby, the electric charges retained in the silicon nitride film is confined into the silicon nitride film, and prevented from moving to a part far from semiconductor substrate 11.

In the eighth step, the side silicon nitride films 27a are removed, so that the volume of the silicon nitride films 27 decreases and thus the number of the trap decreases in addition to the decrease in the number of the trap owing to the thin thickness of silicon nitride films 27. Therefore, the first embodiment of the present invention has charge storage thin films where the mobility of the electric charge is limited in a vertical direction with respect to the surface of the semiconductor substrate, thus preventing the diffusion of the charge in the silicon nitride film 27b when an electric field and various stress such as a thermal stress are applied to the silicon nitride film 27b.

It is to be noted that the present invention can be applied to n-channel or p-channel MOSFET and a method for producting the same.

This application is based on Japanese Patent Application No. 2006-057857 which is hereby incorporated by reference.

What is claimed is:

1. A semiconductor device comprising:
a semiconductor substrate having an element region and a gate electrode part which includes a gate oxide film and a gate electrode formed on said gate oxide film, said gate electrode part being formed on an upper surface of a channel region formed at said element region;
first and second main electrode regions formed in said semiconductor substrate, both of which sandwich said channel region;
silicon oxide films whose thickness are thinner than that of said gate electrode part and substantially uniform, each of said silicon oxide films being formed as an integrated combination of a peripheral silicon oxide film with which an upper surface of said semiconductor substrate surrounding a side of said gate electrode part is covered and a side silicon oxide film with which a side surface of said gate electrode part is covered;
silicon nitride films whose thickness are 100 Å at a maximum, with which upper surfaces of said peripheral silicon oxide films are covered;
side walls respectively formed on upper surfaces of said silicon nitride films, each of which are separated from said side silicon oxide film.

2. A semiconductor device according to claim 1, wherein
each of said silicon nitride films has a thickness in the range of 50 Å to 80 Å.

3. A method for manufacturing a semiconductor device comprising the steps of:
a first step of doping impurities having a first conductive type into an element region of a semiconductor substrate, so as to form a first conductive type impurity region;
a second step of forming a gate electrode part including a gate film and a gate electrode on a part of an upper surface of said first conductive type impurity region;
a third step of forming a silicon oxide precursor film whose thickness is substantially uniform and thinner than that of said gate electrode part, with which a surface of said semiconductor substrate including said gate electrode is covered;
a fourth step of forming a silicon nitride precursor film having a thickness of 100 Å at a maximum, with which a surface of said silicon oxide precursor film is fully covered;
a fifth step of doping impurities having a second conductive type whose conductivity is opposite to said first conductive type into said first conductive type impurity region while using said gate electrode as a mask, so as to form a MOSFET including first and second main electrode regions having said second conductive type and a channel region which exists under said gate electrode part and is sandwiched by said first and second main electrode regions;
a sixth step of forming a side wall precursor film with which a surface of said silicon nitride precursor film is fully covered;
a seventh step of removing said side wall precursor film and a laminated layer having said silicon nitride precursor film and said silicon oxide precursor film excluding peripheral portions surrounding said gate electrode until an upper surface of said gate electrode and an upper surface of said semiconductor substrate except for said peripheral portions are exposed, so as to form side walls from said side wall precursor film, silicon nitride films from said silicon nitride precursor film, and silicon oxide films from said silicon oxide precursor film, each of said silicon oxide films is an integrated combination of a peripheral silicon oxide film with which an upper surface of said semiconductor substrate surrounding said gate electrode part is covered and a side silicon oxide film with which a side surface of said gate electrode part is covered; and
an eighth step of removing side silicon nitride films from said silicon nitride film, each of said side silicon nitride films existing between a side surface of said side walls facing said gate electrode part and a side surface of said gate electrode part, so as to form peripheral silicon nitride films, each of which exists on an upper surface of said peripheral silicon oxide film.

4. A method for manufacturing a semiconductor device according to claim 3,
wherein
in said fourth step, said silicon nitride precursor film is formed so as to have a thickness in the range of 50 to 80 Å, with which a surface of said silicon oxide precursor film is fully covered.
